(19) United States
(12) Patent Application Publication
(10) Pub. No.: US 2010/0237964 A1
(43) Pub. Date: Sep. 23, 2010

(54) HIGH FREQUENCY FILTER

(75) Inventors: Takayuki Teraguchi, Kanagawa-ken (JP); Katsue Kawakyu, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/699,218

(22) Filed: Feb. 3, 2010

(30) Foreign Application Priority Data
Mar. 17, 2009 (JP) 2009-065055

(51) Int. Cl. H03H 7/01

(52) U.S. Cl. 333/174; 333/175

(57) ABSTRACT

A high frequency filter includes: an input terminal; an output terminal; and a variable capacitance circuit provided between the input terminal and the output terminal or between a ground and one of the input terminal and the output terminal, and formed on the semiconductor substrate including a capacitor and a switch element. The switch element is connected in series with the capacitor.

### CROSS-REFERENCE TO RELATED APPLICATIONS

This application is based upon and claims the benefit of priority from the prior Japanese Patent Application No. 2009-065055, filed on Mar. 17, 2009; the entire contents of which are incorporated herein by reference.

### BACKGROUND OF THE INVENTION

1. Field of the Invention

The invention relates to a high frequency filter having variable characteristics.

2. Background Art

It is an important part of receiving performance to remove interference in high-frequency receivers when receiving desired signals. The receiving performance has been improved by using frequency selection filters to extract only the necessary frequency. To improve the receiving performance, it is desirable for receivers to be variable to extract only the necessary frequency according to the frequency of the desired signal.

Frequency selection filters include passive filters and active filters. Passive filters feature good for noise characteristics and distortion characteristics, while active filters feature excellent for loss characteristics and filter characteristics.

It is necessary to have good for noise characteristics and distortion characteristics when used in a high frequency circuit unit, and passive filters may be used. A tunable filter using a varactor diode (for example, refer to JP-A 2002-9573 (Kokai)) and a variable band filter device using a variable capacitance diode (for example, refer to JP-A 2003-23363 (Kokai)) have been proposed as passive filters.

However, a bias current unfortunately is necessary and the nonlinearity of the diode undesirably causes a decline of the distortion characteristics, and to date, only fixed filters have been used in front end units through which high-frequency signals pass.

### SUMMARY OF THE INVENTION

According to an aspect of the invention, there is provided a high frequency filter including: an input terminal; an output terminal; and a variable capacitance circuit provided between the input terminal and the output terminal or between a ground and one of the input terminal and the output terminal, and formed on the semiconductor substrate including a capacitor and a switch element connected in series with the capacitor.

### BRIEF DESCRIPTION OF THE DRAWINGS

FIG. 1 is a circuit diagram illustrating a band-pass filter using a high frequency filter according to an embodiment of the present invention;

FIG. 2 is a schematic view illustrating the states of switch elements for each of the modes of the band pass filter shown in FIG. 1;

FIG. 3 is a schematic view illustrating the characteristic of each of the modes of the band-pass filter shown in FIG. 1;

FIG. 4 illustrates an equivalent circuit of the band-pass filter illustrated in FIG. 1;

FIG. 5 illustrates an equivalent circuit of a fifth-order band-pass filter;

FIGS. 6A and 6B are schematic views illustrating transfer characteristics of a third-order band-pass filter;

FIGS. 7A and 7B are schematic views illustrating other transfer characteristics of the band-pass filter;

FIG. 8 is another circuit diagram illustrating the band-pass filter used in the high frequency filter according to the embodiment of the invention;

FIG. 9 is a schematic view illustrating the transfer characteristics of the band-pass filter illustrated in FIG. 8;

FIG. 10 is another circuit diagram illustrating the band-pass filter using the high frequency filter according to the embodiment of the invention;

FIG. 11 is a schematic view illustrating the transfer characteristics of the band-pass filter illustrated in FIG. 10;

FIG. 12 is another circuit diagram illustrating the band-pass filter using the high frequency filter according to the embodiment of the invention;

FIG. 13 is another circuit diagram illustrating the band-pass filter using the high frequency filter according to the embodiment of the invention;

FIG. 14 illustrates an equivalent circuit of the band-pass filter shown in FIG. 4 when the terminals are shorted;

FIG. 15 is another circuit diagram illustrating the high frequency filter according to the embodiment of the invention;

FIG. 16 illustrates an equivalent circuit of the high frequency filter in FIG. 14 where the second variable capacitance circuit is omitted;

FIG. 17 is another circuit diagram illustrating the high frequency filter according to the embodiment of the invention;

FIG. 18 is a schematic view illustrating the states of the switch elements for each of the modes;

FIG. 19 is a schematic view illustrating the transfer characteristics of the high frequency filter illustrated in FIG. 17;

FIG. 20 is another circuit diagram illustrating the high frequency filter according to the embodiment of the invention; and

FIG. 21 is a schematic view illustrating the transfer characteristics of the high frequency filter illustrated in FIG. 20.

### DETAILED DESCRIPTION OF THE INVENTION

Embodiments of the invention will now be described in detail with reference to the drawings.

In the specification of the application and the drawings, components similar to those described in regard to a drawing thereinabove are marked with like reference numerals, and a detailed description is omitted as appropriate.

### First Embodiment

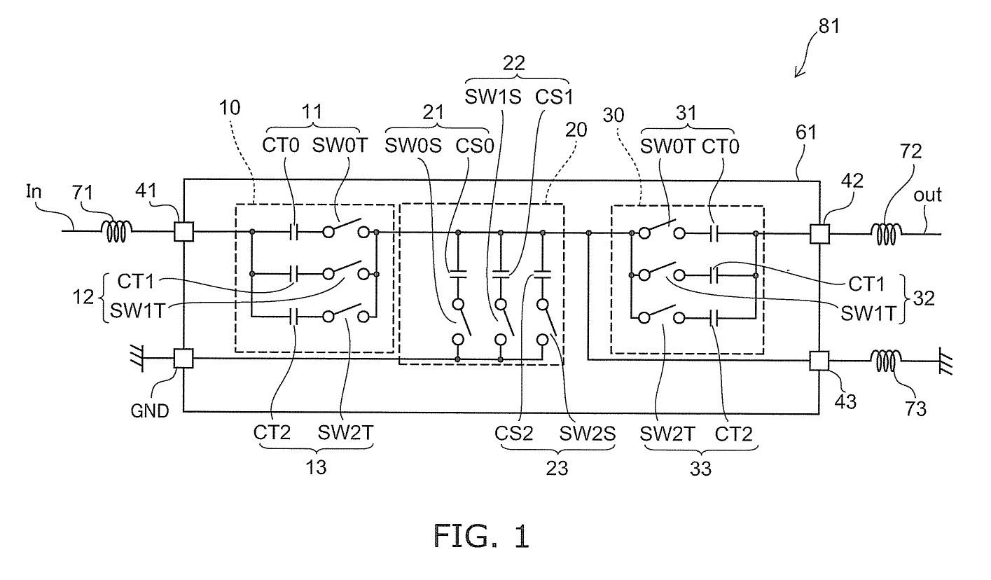

FIG. 1 is a circuit diagram illustrating a band-pass filter using a high frequency filter according to an embodiment of the invention.

As illustrated in FIG. 1, a high frequency filter 61 of this embodiment has a one-chip structure (the portion enclosed by the solid line in the drawing) in which a first variable capacitance circuit 10, a second variable capacitance circuit 20, and a third variable capacitance circuit 30 are formed on the same semiconductor substrate.

Here, each of the first variable capacitance circuit 10, the second variable capacitance circuit 20, and the third variable capacitance circuit 30 has a structure in which three variable capacitance circuits 11 to 13, 21 to 23, and 31 to 33 are connected in parallel, respectively.

Namely, the first variable capacitance circuit 10 (a portion enclosed by a broken line in the drawing) has a structure in which the three variable capacitance circuits 11, 12, and 13 are connected in parallel. Here, the variable capacitance circuit 11 has a structure in which a capacitor CT0 and a switch element SW0T are connected in series. Similarly, each of the variable capacitance circuits 12 and 13 has a structure in which a capacitor CT1 and a switch element SW1T are connected in series and a capacitor CT2 and a switch element SW2T are connected in series, respectively.

Here, an electrostatic capacitance between a semiconductor region on a semiconductor substrate and an electrically conducting film formed thereupon via an insulating film, for example, may be used as each of the capacitors CT0 to CT2. A MOSFET formed on the semiconductor substrate, for example, may be used as each of the switch elements SW0T to SW2T.

The second variable capacitance circuit 20 (a portion enclosed by a broken line in the drawing) has a structure in which the three variable capacitance circuits 21, 22, and 23 are connected in parallel. Each of the variable capacitance circuits 21, 22, and 23 has a structure in which a capacitor CS0 and a switch element SW0S are connected in series, a capacitor CS1 and a switch element SW1S are connected in series, and a capacitor CS2 and a switch element SW2S are connected in series, respectively.

The third variable capacitance circuit 30 (a portion enclosed by a broken line in the drawing) has a structure in which the three variable capacitance circuits 31, 32, and 33 are connected in parallel. Each of the variable capacitance circuits 31 to 33 has a structure in which the capacitor CT0 and the switch element SW0T are connected in series, the capacitor CT1 and the switch element SW1T are connected in series, and the capacitor CT2 and the switch element SW2T are connected in series, respectively.

The high frequency filter illustrated in FIG. 1 is a band-pass filter 81 having a structure in which inductors 71, 72, and 73 are connected to an input terminal 41, an output terminal 42, and a connection point 43 between the first variable capacitance circuit 10 and the second variable capacitance circuit 20 of the high frequency filter 61 of this embodiment. The inductors 71 to 73 may use, for example, chip inductors.

In the high frequency filter 61 illustrated in FIG. 1, the first variable capacitance circuit 10 connects the input terminal 41 to the connection point 43. The second variable capacitance circuit 20 connects the connection point 43 to a ground GND. The third variable capacitance circuit 30 connects the connection point 43 to the output terminal 42. The first variable capacitance circuit 10 and the third variable capacitance circuit 30 are connected in series; the second variable capacitance circuit 20 is connected to the connection point 43 therebetween; and a star configuration is formed.

When the switch element SW0T is ON, the electrostatic capacitance of the variable capacitance circuit 11 is the capacitance of the capacitor CT0; and when the switch element SW0T is OFF, the electrostatic capacitance of the variable capacitance circuit 11 is zero. The electrostatic capacitances of the other variable capacitance circuits 12 and 13 similarly are changed to the electrostatic capacitances of the capacitors CT1 and CT2 by the switch elements SW1T and SW2T, respectively.

Accordingly, the electrostatic capacitances of the first and third variable capacitance circuits 10 and 30 in which the variable capacitance circuits 11 to 13 and 31 to 33 are connected in parallel can be changed according to the switch elements SW0T to SW2T being ON or OFF.

For example, by switching any one of the switch elements SW0T to SW2T ON and switching the others OFF, the electrostatic capacitance of the first and third variable capacitance circuits 10 and 30 can be changed to the electrostatic capacitances of the capacitors CT0, CT1, and CT2, respectively.

To reduce the surface area necessary to form the capacitors CT0 to CT2, it is desirable to switch the switch elements SW0T to SW2T ON one at a time such that the number switched ON increases simultaneously to two and three.

Similarly, the electrostatic capacitances of the second and third variable capacitance circuits 20 and 30 can be changed to the electrostatic capacitances of the capacitors CS0 to CS2 and CT0 to CT2 by switching ON and OFF the switch elements SW0S to SW2S and SW0T to SW2T.

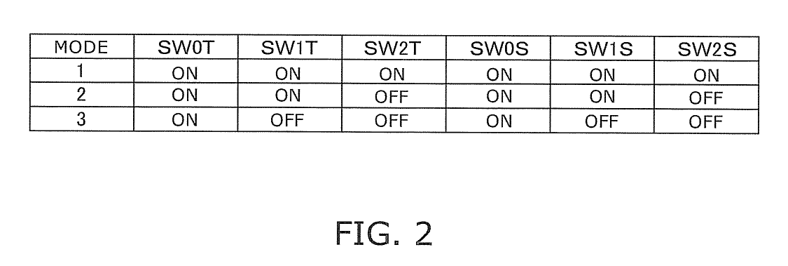

The various methods may be applied to control the switch elements SW0T to SW2T of the first and third variable capacitance circuits 10 and 30 and the switch elements SW0S to SW2S of the second variable capacitance circuit 20, for example, as illustrated in FIG. 2. FIG. 2 illustrates a control example in which the number of the switch elements SW0T to SW2T and SW0S to SW2S in the ON state increases for each of modes 1, 2, and 3.

As illustrated in FIG. 2, in mode 1, all of the switch elements SW0T to SW2S are ON. In mode 2, two of each, i.e., the switch elements SW0T, SW1T, SW0S, and SW1S, are ON; and the other switch elements SW2T and SW2S are OFF. In mode 3, one of each, i.e., the switch elements SW0T and SW0S, are ON; and the other switch elements SW1T, SW2T, SW1S, and SW2S are OFF. Thus, the electrostatic capacitances of the first and third variable capacitance circuits 10 and 30 and the second variable capacitance circuit 20 have maximum values in mode 1, minimum values in mode 3, and intermediate values in mode 2.

For example, the electrostatic capacitances of the capacitors CT0, CT1, and CT2 are taken to be 1 pF, 0.5 pF, and 0.5 pF, respectively. The electrostatic capacitances of the capacitors CS0, CS1, and CS2 are taken to be 10 pF, 5 pF, and 5 pF, respectively. When each of the first and third variable capacitance circuits 10 and 30 and the second variable capacitance circuit 20 is in mode 1, the electrostatic capacitances are 2 pF and 20 pF, respectively; in mode 2, 1.5 pF and 15 pF, respectively; and in mode 3, 1 pF and 10 pF, respectively.

In the case where each of the modes is switched, it is desirable to control the switch elements SW0T to SW2T and SW0S to SW2S to switch synchronously to avoid disturbance of the transfer characteristics. For example, in the case where mode 1 is switched to mode 2, it is desirable to control the switch elements SW2T and SW2S to switch OFF simultaneously.

For example, in the case where the electrostatic capacitances of the capacitors CT0 to CS2 have the values recited above, in mode 1, the electrostatic capacitances of the first and third variable capacitance circuits 10 and 30 and the second variable capacitance circuit 20 are 2 pF and 20 pF, respectively. It is desirable to control the electrostatic capacitances to change simultaneously from these values to the electrostatic capacitances of mode 2 of 1.5 pF and 15 pF to reduce disturbance when changing the filter characteristic. This holds similarly for the other embodiments recited below.

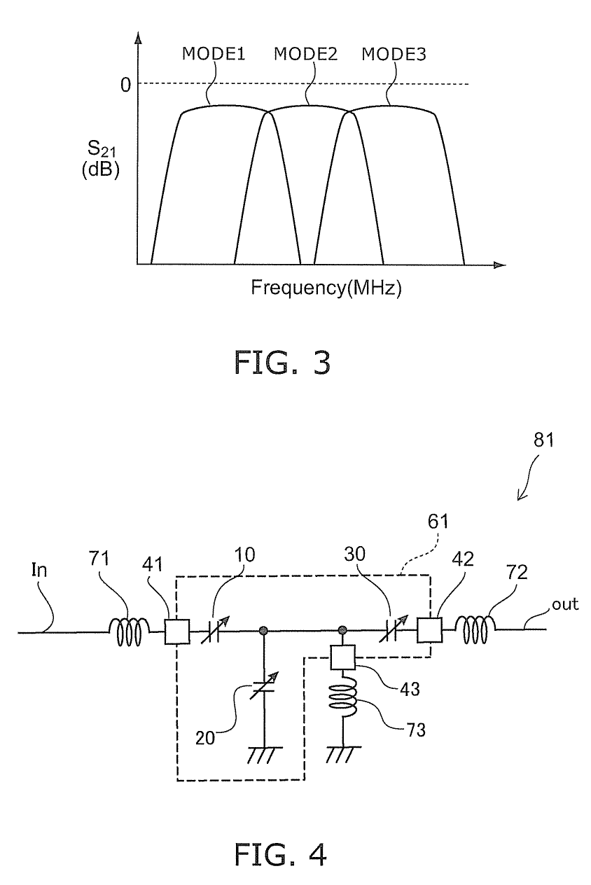

FIG. 3 is a schematic view illustrating the characteristic of each of the modes of the band-pass filter illustrated in FIG. 1.

As illustrated in FIG. 3, the high frequency filter 61 of this embodiment may form the band-pass filter 81 which is variable to the three different transfer characteristics of the modes 1 to 3, that is, the transfer characteristics having different characteristic frequencies, i.e., frequencies at the boundaries between stopbands and passbands.

The characteristic frequencies defining the boundaries between the passbands and the stopbands in the band-pass filter 81 change to minimum frequencies in mode 1, maximum frequencies in mode 3, and intermediate frequencies in mode 2. Thus, the band-pass filter 81 using the high frequency filter 61 is a variable-frequency high frequency filter.

For example, by using the band-pass filter 81 in a television broadcast receiving tuner, the band-pass filter 81 may be used as a variable-frequency band-pass filter in the digital band (470 MHz to 770 MHz). By switching among modes 1 to 3, signals of the passbands of the band-pass filter 81 may be selected from the digital band to improve receiving performance.

FIG. 4 illustrates an equivalent circuit of the band-pass filter illustrated in FIG. 1.

As illustrated in FIG. 4, the high frequency filter 61 of this embodiment has a star configuration in which the first and third variable capacitance circuits 10 and 30 are connected in series between the input terminal 41 and the output terminal 42 and the second variable capacitance circuit 20 is further connected between the ground and the connection point 43 between the first and third variable capacitance circuits 10 and 30. The band-pass filter 81 may be formed by connecting the inductors 71 to 73 to the input terminal 41, the output terminal 42, and the connection point 43.

The band-pass filter 81 illustrated in FIG. 4 is a third-order filter and may form a Butterworth filter or a Chebyshev filter.

By similarly adding variable capacitance circuits, a band-pass filter of higher orders may be provided.

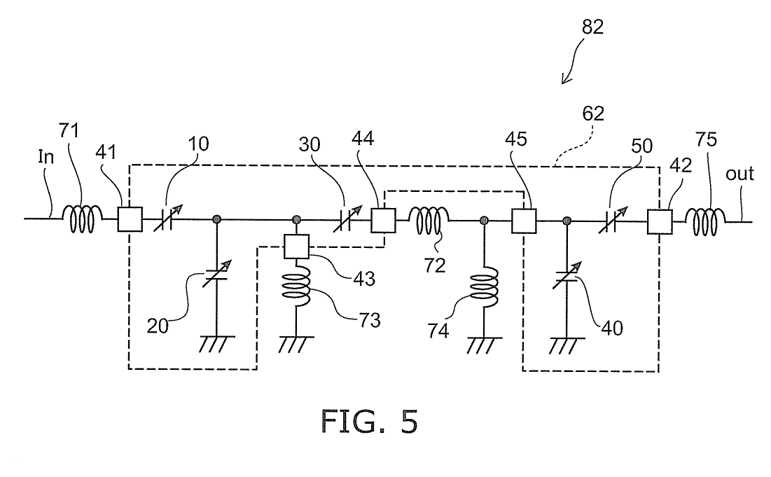

FIG. 5 illustrates an equivalent circuit of a fifth-order band-pass filter.

As illustrated in FIG. 5, a high frequency filter 62 of this embodiment (the portion enclosed by the broken line) has a one-chip structure in which the first variable capacitance circuit 10, the second variable capacitance circuit 20, the third variable capacitance circuit 30, a fourth variable capacitance circuit 40, and a fifth variable capacitance circuit 50 are formed on the same semiconductor substrate.

Here, each of the first to third variable capacitance circuits 10 to 30 may have three variable capacitance circuits connected in parallel similar to those illustrated in FIG. 1 or any number of variable capacitance circuits connected in parallel. Each of the fourth and fifth variable capacitance circuits 40 and 50 also may have any number of multiple variable capacitance circuits connected in parallel.

The portion in which the first, second, and third variable capacitance circuits 10, 20, and 30 are connected in a star configuration among the input terminal 41, a terminal 44, the ground, and the connection point 43 is similar to the high frequency filter 61 of the third-order band-pass filter 81 illustrated in FIG. 4. Additionally in this configuration, the fifth variable capacitance circuit 50 is connected between a terminal and the output terminal 42, and the fourth variable capacitance circuit 40 is connected between the terminal 45 and the ground.

A fifth-order band-pass filter 82 may be formed by connecting the inductors 71 to 75 to the input terminal 41, the output terminal 42, the connection point 43, and the terminals 44, and 45, respectively, of the high frequency filter 62.

Although this embodiment illustrates a configuration in which the fifth-order band-pass filter 82 includes the first to third variable capacitance circuits 10, 20 and 30 connected in a star configuration and the fourth and fifth variable capacitance circuits 40 and 50 connected in series, the invention is not limited thereto. One variable capacitance circuit may be added to the first to third variable capacitance circuits 10, 20, and 30 connected in the star configuration and an inductor may be connected externally to form a fourth-order band-pass filter. Similarly, one variable capacitance circuit and two variable capacitance circuits connected in series may be added to form a high frequency filter using a band-pass filter of even higher orders.

Also, a one-chip configuration in which only the input terminal 41, the connection point 43 as an output terminal, and the first variable capacitance circuit 10 are formed on a semiconductor substrate may be used as a high frequency filter. Further, a one-chip configuration in which only the connection point 43 as an input/output terminal and the second variable capacitance circuit 20 connected between the connection point 43 and the ground GND are formed on a semiconductor substrate may be used as a high frequency filter.

However, the sensitivity of the elements increase as the order of the filter increases, and the transfer characteristics greatly deteriorate due to the error of each element. The effects of parasitic inductors and parasitic capacitances also increase due to an increased number of terminals and externally connected inductors 71 to 75.

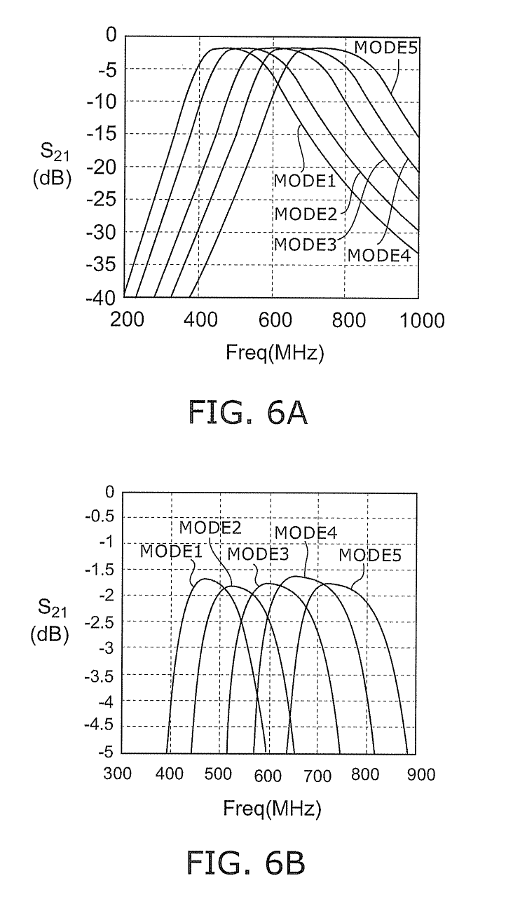

FIGS. 6A and 6B are schematic views illustrating transfer characteristics of a third-order band-pass filter.

FIG. 6A illustrates the transfer characteristics of five modes having different characteristic frequencies, where the frequency is plotted on the horizontal axis and an S parameter S₂₁ (the transfer characteristic in the forward direction) is plotted on the vertical axis.

FIG. 6B illustrates the transfer characteristics S₂₁ illustrated in FIG. 6A, where the portion of −5 to 0 dB in the vertical axis direction and 300 to 900 MHz in the horizontal axis direction is enlarged.

As illustrated in FIG. 6B, the deviation of the transfer characteristics S₂₁ of the passbands is within ±0.1 dB of the design value.

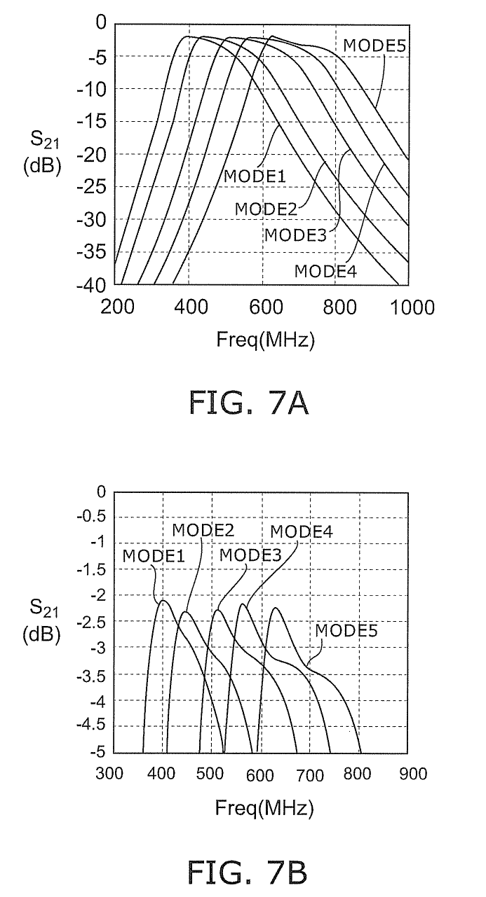

FIGS. 7A and 7B are a schematic view illustrating other transfer characteristics of the band-pass filter.

FIGS. 7A and 7B illustrate a calculation example of the transfer characteristics when 0.5 nH parasitic inductors are added to the external inductors 71 and 73 having design values of 20 nH.

As illustrated in FIG. 7A, the transfer characteristics S₂₁ are disturbed. FIG. 7B illustrates the transfer characteristics S₂₁ illustrated in FIG. 7A, where the portion of −5 to 0 dB in the vertical axis direction and 300 to 900 MHz in the horizontal axis direction is enlarged.

As illustrated in FIG. 7B, the deviation of the passbands deteriorates greatly.

Accordingly, in the case where, for example, the capacitors CT0 to CS2 and the switch elements SW0T to SW2S forming the variable capacitance circuits 11 to 33 are not formed on the same semiconductor substrate, the transfer characteristics deteriorate due to parasitic capacitances, parasitic inductors, etc., of interconnects among the capacitors CT0 to CS2 and the switch elements SW0T to SW2S.

Conversely, according to the high frequency filter 61 of this embodiment, the deterioration of the transfer characteristics due to the interconnects recited above can be reduced by the one-chip structure in which the variable capacitance circuits 11 to 33 including the capacitors CT0 to CS2 and the switch elements SW0T to SW2S are formed on the same semiconductor substrate.

However, in the case of a one-chip structure formed on the same semiconductor substrate as in the high frequency filter 61 of this embodiment, it is desirable to use filters having low element sensitivities to ensure the characteristics.

In the high frequency filter 61 of this embodiment, the variable capacitance circuits 11 to 13 and 31 to 33 forming the first and third variable capacitance circuits 10 and 30 have structures in which the capacitors CT0 to CT2 and the switch elements SW0T to SW2T are connected in series, respectively, and the variable capacitance circuits 21 to 23 forming the second variable capacitance circuit 20 have structures in which the capacitors CS0 to CS2 and the switch elements SW0S to SW2S are connected in series.

Therefore, when the switch elements SW0T to SW2S are switched ON, the ON resistances of the switch elements SW0T to SW2S enter in series into the capacitors CT0 to CS2, respectively, and the Q of the circuits decrease. When the switch elements SW0T to SW2S are OFF, the parasitic capacitances thereof enter in parallel into the capacitors CT0 to CS2, respectively.

However, the switch elements SW0T and SW0S are constantly ON. Therefore, the switch elements SW0T and SW0S may be omitted, and the capacitors CT0 and CS0 may be constantly in a connected state.

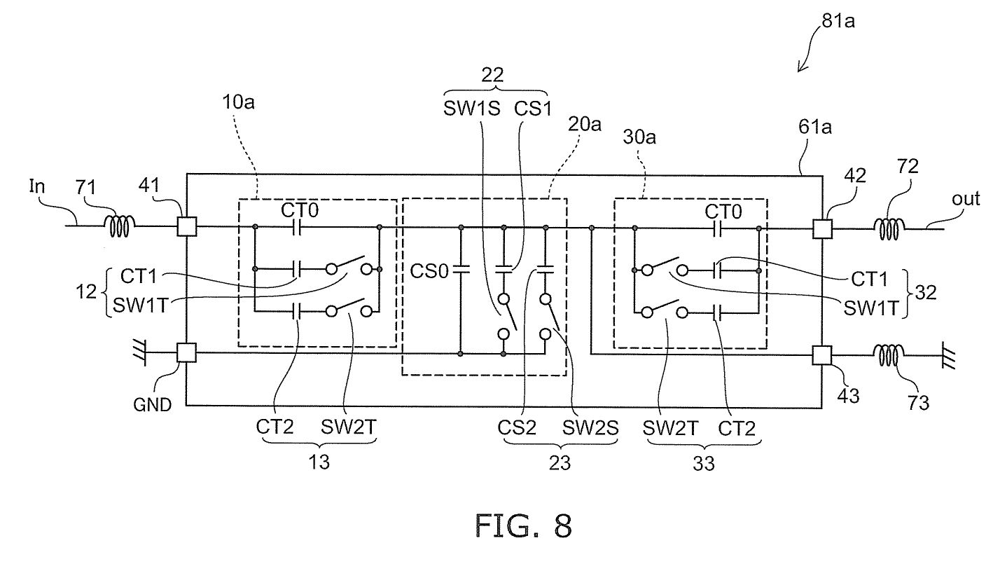

FIG. 8 is another circuit diagram illustrating the band-pass filter used in the high frequency filter according to the embodiment of the invention.

A high frequency filter 61a of this embodiment illustrated in FIG. 8 has a one-chip structure (the portion enclosed by the solid line in the drawing) in which fourth and sixth variable capacitance circuits 10a and 30a and a fifth variable capacitance circuit 20a are connected in a star configuration and formed on the same semiconductor substrate.

In other words, the high frequency filter 61a of this embodiment has a structure in which the first and third variable capacitance circuits 10 and 30 and the second variable capacitance circuit 20 of the high frequency filter 61 illustrated in FIG. 1 are replaced with the fourth and sixth variable capacitance circuits 10a and 30a and the fifth variable capacitance circuit 20a, respectively.

Here, the fourth variable capacitance circuit 10a (a portion enclosed by a broken line in the drawing) has a structure in which two of the variable capacitance circuits 12 and 13 and the capacitor CT0 are connected in parallel. In other words, the capacitor CT0 is in a state of being constantly connected in a structure in which the switch element SW0T is omitted from the variable capacitance circuit 11 recited above. Each of the variable capacitance circuits 12 and 13 has a structure in which the capacitor CT1 and the switch element SW1T are connected in series, and the capacitor CT2 and the switch element SW2T are connected in series, respectively.

Similarly, the fifth variable capacitance circuit 20a (a portion enclosed by a broken line in the drawing) has a structure in which two of the variable capacitance circuits 22 and 23 and the capacitor CS0 are connected in parallel. In other words, the capacitor CS0 is in a state of being constantly connected in a structure in which the switch element SW0S is omitted from the variable capacitance circuit 21 recited above. Each of the variable capacitance circuits 22 and 23 has a structure in which the capacitor CS1 and the switch element SW1S are connected in series, and the capacitor CS2 and the switch element SW2S are connected in series, respectively.

Similarly, the sixth variable capacitance circuit 30a (a portion enclosed by a broken line in the drawing) has a structure in which two of the variable capacitance circuits 32 and 33 and the capacitor CT0 are connected in parallel. The variable capacitance circuits 32 and 33 are similar to the variable capacitance circuits 12 and 13 recited above.

Thus, the Q of the circuit can be increased by omitting the switch elements SW0T and SW0S, and the loss characteristics of the filter can be improved. Also, the effects of the parasitic capacitances of the switch elements SW0T and SW0S can be eliminated.

The circuit illustrated in FIG. 8 is a band-pass filter 81a having a structure in which the inductors 71, 72, and 73 are connected to the input terminal 41, the output terminal 42, and the connection point 43 of the high frequency filter 61a of this embodiment.

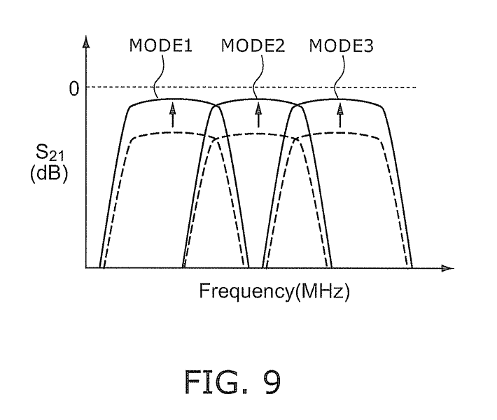

FIG. 9 is a schematic view illustrating the transfer characteristics of the band-pass filter illustrated in FIG. 8.

In the band-pass filter 81a illustrated in FIG. 9, there is little attenuation of the passbands by the resistance components of the switch elements SW0T and SW0S, and the loss characteristics of the filter are improved. The broken lines in FIG. 9 are schematic views of the transfer characteristics of the band-pass filter 81 illustrated for comparison.

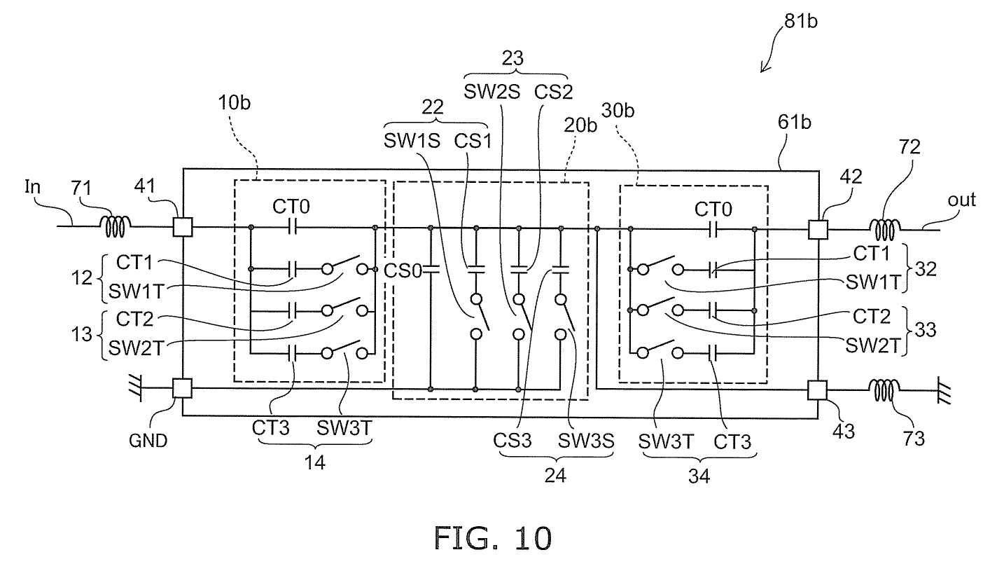

FIG. 10 is another circuit diagram illustrating the band-pass filter using the high frequency filter according to the embodiment of the invention.

As illustrated in FIG. 10, a high frequency filter 61b of this embodiment has a one-chip structure (the portion enclosed by the solid line in the drawing) in which seventh and ninth variable capacitance circuits 10b and 30b and an eighth variable capacitance circuit 20b are connected in a star configuration and formed on the same semiconductor substrate.

In other words, the high frequency filter 61b of this embodiment has a structure in which the fourth and sixth variable capacitance circuits 10a and 30a and the fifth variable capacitance circuit 20a of the high frequency filter 61a illustrated in FIG. 8 are replaced with the seventh and ninth variable capacitance circuits 10b and 30b and the eighth variable capacitance circuit 20b, respectively.

The seventh variable capacitance circuit 10b (a portion enclosed by a broken line in the drawing) has a structure in which the three variable capacitance circuits 12, 13, and 14 and the capacitor CT0 are connected in parallel. Here, the capacitor CT0 and the variable capacitance circuits 12 and 13 are similar to those of the high frequency filter 61a recited above. The variable capacitance circuit 14 has a structure in which a capacitor CT3 and a switch element SW3T are connected in series.

Similarly, the eighth variable capacitance circuit 20b (a portion enclosed by a broken line in the drawing) has a structure in which the three variable capacitance circuits 22, 23, and 24 and the capacitor CS0 are connected in parallel. Here, the capacitor CS0 and the variable capacitance circuits 22 and 23 are similar to those of the high frequency filter 61a. The variable capacitance circuit 24 has a structure in which a capacitor CS3 and a switch element SW3S are connected in series.

The ninth variable capacitance circuit 30b (a portion enclosed by a broken line in the drawing) has a structure in which the three variable capacitance circuits 32, 33, and 34 and the capacitor CT0 are connected in parallel. Here, the variable capacitance circuits 32 to 34 are similar to the variable capacitance circuits 12 to 14 of the seventh variable capacitance circuit 10b recited above.

The circuit illustrated in FIG. 10 is a band-pass filter 81b having a structure in which the inductors 71, 72, and 73 are connected to the input terminal 41, the output terminal 42, and the connection point 43 of the high frequency filter 61b of this embodiment.

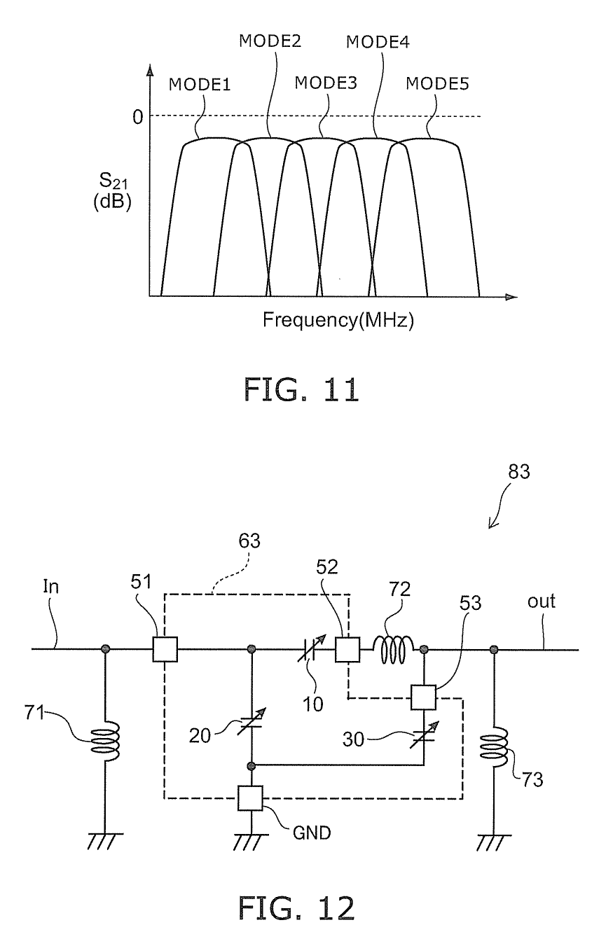

Thus, the high frequency filter 61b of this embodiment has a configuration in which one more system is added to the fourth and sixth variable capacitance circuits 10a and 30a and the fifth variable capacitance circuit 20a of the high frequency filter 61a. Although eight, i.e., two to the third power, patterns of characteristic frequencies are possible by the ON and OFF of the switch elements SW1T to SW3T and SW1S to SW3S, combinations occur with substantially the same frequency characteristics. Therefore, about five switching levels are appropriate. The resulting transfer characteristics of the band-pass filter are illustrated schematically in FIG. 11.

In the high frequency filter 61b of this embodiment, each of the seventh, eighth, and ninth variable capacitance circuits 10b, 20b and 30b include the three variable capacitance circuits 12 to 14, 22 to 24, and 32 to 34, and the capacitors CT0, CS0, and CT0, respectively. However, the invention is not limited thereto. Any number of switchable band-pass filters may be formed using any number of variable capacitance circuits having similar configurations. This holds similarly for the other embodiments.

In the case where the switch elements SW0T to SW2S are formed of, for example, MOSFETs, the ON resistance of the switch elements SW0T to SW2S enter in series into the capacitors CT0 to CS2, respectively, and the Q of the circuits decrease. Accordingly, it is desirable to have low ON resistances of the switch elements SW0T to SW2S.

However, the Q of the circuits of the variable capacitance circuits 11 to 23 is inversely proportional to the product of the ON resistance of the electrostatic capacitances of the capacitors CT0 to CS2 and the MOSFETs connected in series with the capacitors CT0 to CS2. Therefore, the Q of the circuits of the variable capacitance circuits 11 to 23 can be made substantially constant by setting the ON resistances to be inversely proportional to the electrostatic capacitances of the capacitors CT0 to CS2.

Thus, the ON resistance of a MOSFET connected in series with a low electrostatic capacitance can be set high by, for example, reducing the gate width. Moreover, reducing the gate width reduces the parasitic capacitance of the MOSFET. Accordingly, MOSFETs having low parasitic capacitances may be connected in series with capacitors having low electrostatic capacitances, which is desirable also from the point of element sensitivity.

However, in addition to the T filter illustrated in FIG. 4, a band-pass filter may be formed of a π filter such as that illustrated in FIG. 12.

As illustrated in FIG. 12, a high frequency filter 63 (the portion enclosed by the broken line) of this embodiment includes three variable capacitance circuits, i.e., the first variable capacitance circuit 10, the second variable capacitance circuit 20, and the third variable capacitance circuit 30, connected in series between an input terminal 52 and an output terminal 53. A band-pass filter 83 can be formed to receive an input signal by a connection point 51 and output an output signal from the output terminal 53 by connecting the inductors 71 to 73 to the connection point 51 between the first variable capacitance circuit 10 and the second variable capacitance circuit 20 connected in series, the input terminal 52, and the output terminal 53, respectively. The connection point GND between the second variable capacitance circuit 20 and the third variable capacitance circuit 30 connected in series is ground.

Although a configuration is illustrated in this embodiment in which three variable capacitance circuits, i.e., the first to third variable capacitance circuits 10, 20, and 30, are connected in series, the invention is not limited thereto. High-order filters may be formed by connecting any number of variable capacitance circuits in series and externally connecting inductors.

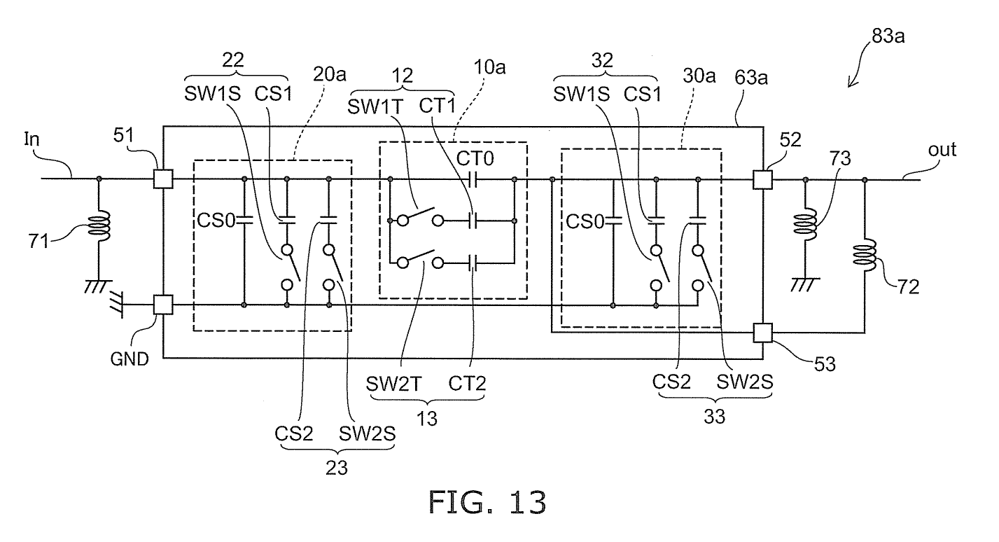

FIG. 13 is another circuit diagram illustrating the band-pass filter using the high frequency filter according to the embodiment of the invention.

As illustrated in FIG. 13, a high frequency filter 63a of this embodiment has a one-chip structure (the portion enclosed by the solid line in the drawing) in which the fourth variable capacitance circuit 10a, the fifth variable capacitance circuit 20a, and the sixth variable capacitance circuit 30a are connected in series and formed on the same semiconductor substrate.

In other words, the high frequency filter 63a of this embodiment has a configuration in which the first variable capacitance circuit 10, the second variable capacitance circuit 20, and the third variable capacitance circuit 30 of the high frequency filter 63 illustrated in FIG. 12 are replaced with the fourth variable capacitance circuit 10a, the fifth variable capacitance circuit 20a, and the sixth variable capacitance circuit 30a, respectively.

The fourth variable capacitance circuit 10a and the fifth variable capacitance circuit 20a are similar to those of the high frequency filter 61a illustrated in FIG. 8.

Similar to the fifth variable capacitance circuit 20a, the sixth variable capacitance circuit 30a includes the two variable capacitance circuits 32 and 33 connected in parallel and the capacitor CS0.

Similarly to the band-pass filter 81a illustrated in FIG. 8, a variable-frequency filter of modes 1 to 3 can be formed by switching the switch elements SW1T to SW2S.

The circuit illustrated in FIG. 13 is a π band-pass filter 83a having a structure in which the inductors 71, 72, and 73 are connected to the C 51, the input terminal 52, and the output terminal 53, respectively, of the high frequency filter 63a of this embodiment. The band-pass filter 83a has a configuration in which an input signal is input into the connection point 51 and an output signal is output from the output terminal 53. The inductors 71 to 73 may use, for example, chip inductors.

Although embodiments of high frequency filters usable in band-pass filters are described above, high frequency filters also may be configured to have characteristics of low-pass filters, high-pass filters, and band-eject filters by modifying the variable capacitance circuits and the connection points of the externally connected inductors of the high frequency filter.

However, low-pass filters are often necessary for receivers.

For example, in a television broadcast receiving tuner, signals of the analog band (40 MHz to 470 MHz) cannot be received when using a variable-frequency band-pass filter of the digital band (470 MHz to 770 MHz).

It is possible to use a configuration that switches among a variable-frequency band-pass filter, a pass-through mode by an external switch, or a separately provided low-pass filter. Receiving is possible by using the variable-frequency band-pass filter in the digital band (470 MHz to 770 MHz) and using a pass-through mode by switching by the external switch or a separately provided low-pass filter for the signal in the analog band (40 MHz to 470 MHz).

However, in this embodiment, because the high frequency filter for the variable-frequency band-pass filter is integrated on one chip, it is desirable to be able to realize the low-pass filter on the same chip.

Therefore, to add a mode of a low-pass filter, a low-pass filter is formed by adding a switch inside the band-pass filter. Thereby, it is possible to realize the band-pass filter and the low-pass filter on one chip.

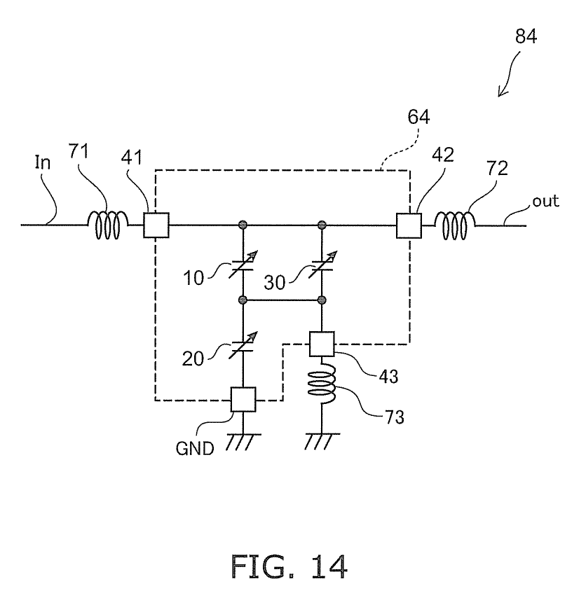

Turning once again to the equivalent circuit of the band-pass filter of FIG. 4, the case where the input terminal 41 and the output terminal 42 are shorted becomes the equivalent circuit illustrated in FIG. 14.

Although having somewhat large ripples, a circuit 64 illustrated in FIG. 14 may be used as a low-pass filter 84. The adjustable-frequency low-pass filter 84 is formed by changing the capacitances of the first and third variable capacitance circuits 10 and 30 and the second variable capacitance circuit 20.

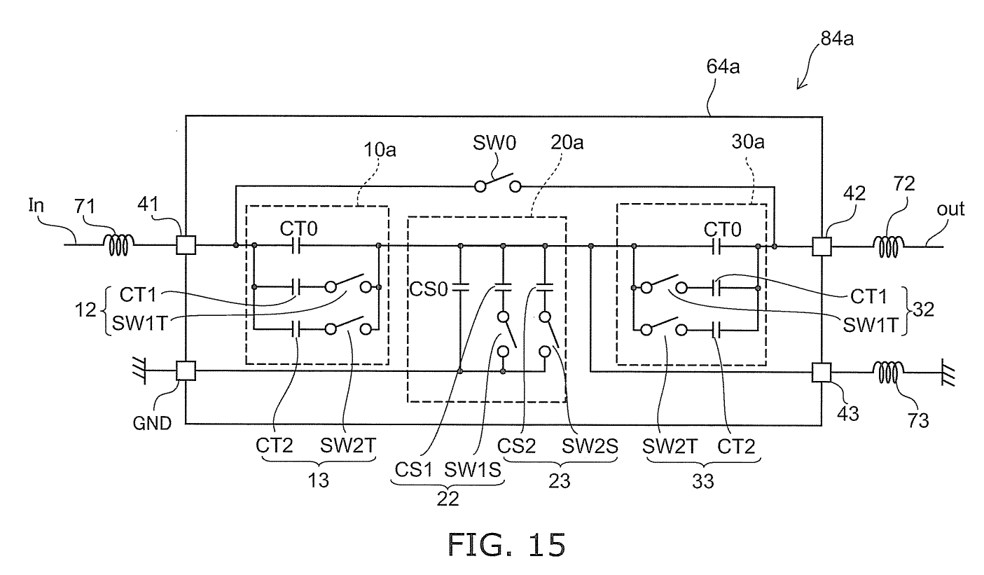

FIG. 15 is another circuit diagram illustrating the high frequency filter according to the embodiment of the invention.

As illustrated in FIG. 15, a high frequency filter 64a of this embodiment has a one-chip structure (the portion enclosed by the solid line in the drawing) in which the fourth variable capacitance circuit 10a, the fifth variable capacitance circuit 20a, the sixth variable capacitance circuit 30a, and a switch element SW0 are formed on the same semiconductor substrate. Except for including the switch element SW0 to provide a short or an open circuit between the input terminal 41 and the output terminal 42, the high frequency filter 64a of this embodiment is similar to the high frequency filter 61a illustrated in FIG. 8.

A high frequency filter 84a illustrated in FIG. 15 has a structure in which the inductors 71, 72, and 73 are connected to the input terminal 41, the output terminal 42, and the connection point 43, respectively, of the high frequency filter 64a of this embodiment.

The switch element SW0 is connected to provide a short or an open circuit between the input terminal 41 and the output terminal 42. In the case where the switch element SW0 is switched ON, the high frequency filter 64a of this embodiment has the configuration of the equivalent circuit illustrated in FIG. 14. In the case where the switch element SW0 is switched OFF, the high frequency filter 64a has the configuration of the band-pass filter 81a illustrated in FIG. 8.

Thus, a variable filter having both a band-pass mode and a low-pass mode can be formed by using the high frequency filter 64a of this embodiment.

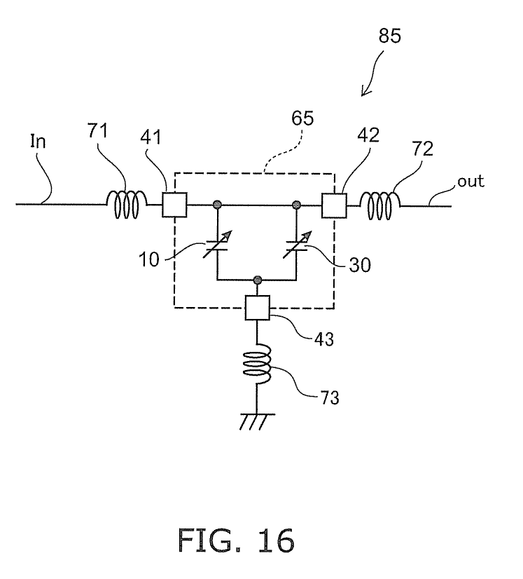

However, in the case where the second variable capacitance circuit 20 is omitted from the equivalent circuit of FIG. 14, the high frequency filter 64 becomes the equivalent circuit enclosed by the broken line in FIG. 16.

A high frequency filter 85 illustrated in FIG. 16 has a characteristic with transmission zeros and can realize, for example, a low-pass filter having good frequency characteristics by forming an elliptic filter.

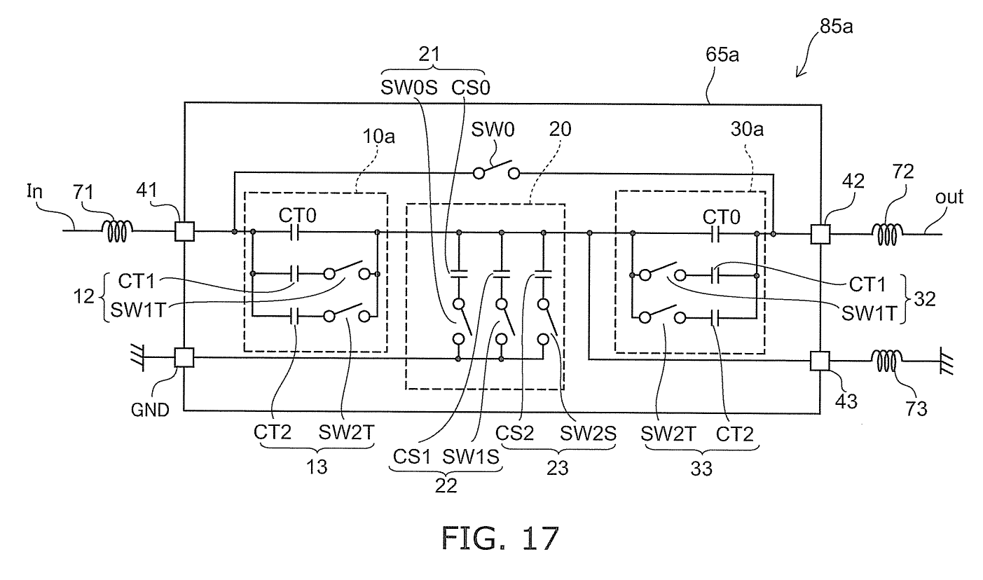

FIG. 17 is another circuit diagram illustrating the high frequency filter according to the embodiment of the invention.

As illustrated in FIG. 17, a high frequency filter 65a of this embodiment has a one-chip structure (the portion enclosed by the solid line in the drawing) in which the fourth variable capacitance circuit 10a, the second variable capacitance circuit 20, the sixth variable capacitance circuit 30a, and the switch element SW0 are formed on the same semiconductor substrate. The fourth variable capacitance circuit 10a, the second variable capacitance circuit 20, and the sixth variable capacitance circuit 30a are connected in a star configuration. Each of the terminals of the fourth and sixth variable capacitance circuits 10a and 30a and the second variable capacitance circuit 20 is electrically connected to an external terminal. In other words, the high frequency filter 65a of this embodiment has a configuration in which the fifth variable capacitance circuit 20a of the high frequency filter 64a illustrated in FIG. 15 is replaced with the second variable capacitance circuit 20.

Here, the fourth and sixth variable capacitance circuits 10a and 30a are similar to those illustrated in FIG. 8; and the second variable capacitance circuit 20 is similar to that illustrated in FIG. 1. In other words, the fourth and sixth variable capacitance circuits 10a and 30a have configurations in which one capacitor, i.e., the capacitor CT0, is constantly connected; and the variable capacitance circuits 12, 13, 32, and 33 can be switched ON and OFF by the switch elements SW1T and SW2T. All of the variable capacitance circuits 21 to 23 of the second variable capacitance circuit 20 can be switched ON and OFF by the switch elements SW0S to SW2S.

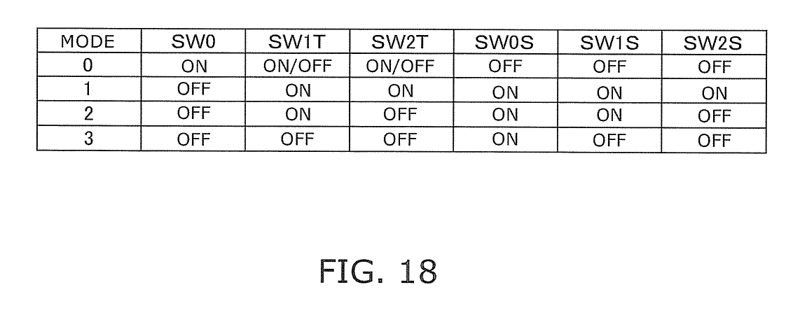

FIG. 18 is a schematic view illustrating the states of the switch element SW0 and the switch elements SW1T to SW2S of each mode.

In mode 1 to 3, the switch element SW0 is OFF. In mode 0, the switch element SW0 is ON. Also in mode 0, the switch elements SW0S to SW2S are OFF; and the characteristic frequency of the low-pass filter can be changed by switching the switch elements SW1T to SW2T ON and OFF.

In mode 1, all of the switch elements SW1T to SW2S are ON. In mode 2, the switch elements SW1T, SW0S, and SW1S are ON and the other switch elements SW2T and SW2S are OFF. In mode 3, the switch element SW0S is ON and the other switch elements SW1T, SW2T, SW1S, and SW2S are OFF. Thus, the electrostatic capacitances of the fourth and sixth variable capacitance circuits 10a and 30a and the second variable capacitance circuit 20 have maximum values in mode 1, minimum values in mode 3, and intermediate values in mode 2.

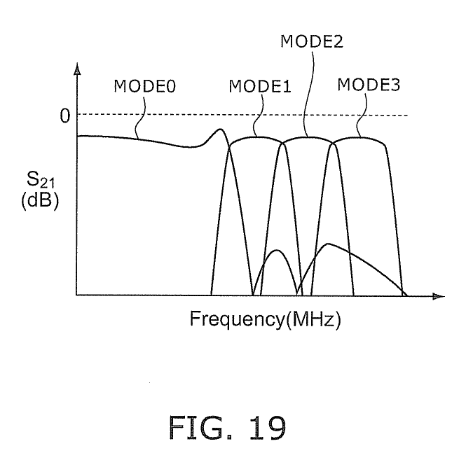

FIG. 19 is a schematic view illustrating the transfer characteristics of the high frequency filter illustrated in FIG. 17.

As illustrated in FIG. 19, a high frequency filter 85a using the high frequency filter 65a of this embodiment is a low-pass filter in mode 0, and the characteristic of an elliptic filter is illustrated.

The filter is a band-pass filter in modes 1 to 3, and the characteristics of a Butterworth filter or a Chebyshev filter can be realized.

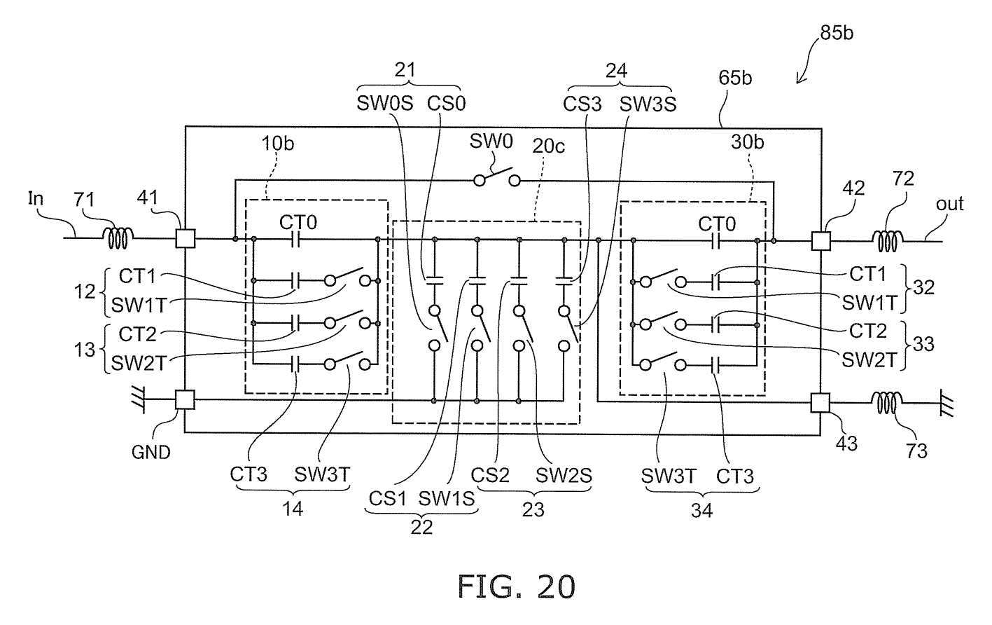

FIG. 20 is another circuit diagram illustrating the high frequency filter according to the embodiment of the invention.

As illustrated in FIG. 20, a high frequency filter 65b of this embodiment illustrates the case where the seventh and ninth variable capacitance circuits 10b and 30b include the three variable capacitance circuits 12 to 14 and 32 to 34 and the capacitor CT0, respectively, and an eighth variable capacitance circuit 20c includes four variable capacitance circuits 21 to 24. Otherwise, the high frequency filter 65b is similar to the high frequency filter 65a illustrated in FIG. 17.

A high frequency filter 85b using the high frequency filter 65b is a low-pass filter of the equivalent circuit illustrated in FIG. 16 in mode 0 when the switch element SW0 is ON.

In modes 1 to 5 when the switch element SW0 is OFF, the configuration is similar to that of the band-pass filter 81b illustrated in FIG. 10.

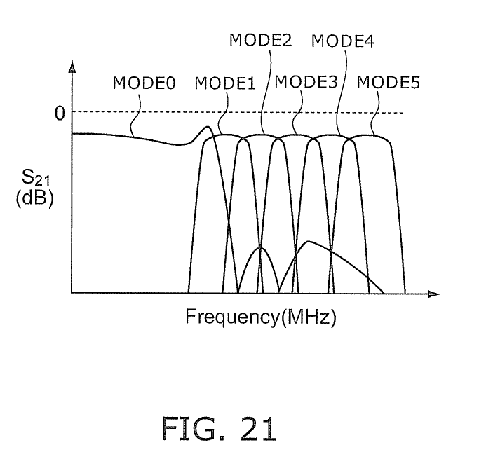

FIG. 21 is a schematic view illustrating the transfer characteristics of the high frequency filter illustrated in FIG. 20.

As illustrated in FIG. 21, by using the high frequency filter 65b of this embodiment, it is possible to form a low-pass filter capable of adjusting the characteristic frequency and a band-pass filter capable of switching among multiple levels of characteristic frequencies by connecting the inductors 71 to 73 to the input terminal 41, the output terminal 42, and the connection point 43, respectively.

Hereinabove, exemplary embodiments of the invention are described with reference to specific examples. However, the invention is not limited to these specific examples. For example, one skilled in the art may appropriately select specific configurations of components of high frequency filters from known art and similarly practice the invention. Such practice is included in the scope of the invention to the extent that similar effects thereto are obtained.

Further, any two or more components of the specific examples may be combined within the extent of technical feasibility; and are included in the scope of the invention to the extent that the purport of the invention is included.

Moreover, all high frequency filters practicable by an appropriate design modification by one skilled in the art based on the high frequency filters described above as exemplary embodiments of the invention also are within the scope of the invention to the extent that the purport of the invention is included.

Furthermore, various modifications and alterations within the spirit of the invention will be readily apparent to those skilled in the art. All such modifications and alterations should therefore be seen as within the scope of the invention.

1. A high frequency filter comprising:
an input terminal;
an output terminal; and
a variable capacitance circuit provided between the input terminal and the output terminal or between a ground and one of the input terminal and the output terminal, and formed on the semiconductor substrate including a capacitor and a switch element connected in series with the capacitor.

2. The filter according to claim 1, the filter including:
at least two of the variable capacitance circuits connected in series at a connection point; and
at least one of the variable capacitance circuits connecting the connection point and the ground, an inductor being to be connected to at least one selected from the input terminal, the output terminal, and the connection point, wherein
electrostatic capacitances of the at least two of the variable capacitance circuits and the at least one of the variable capacitance circuits are variable by controlling the switch element, and
a characteristic frequency are variable by controlling the switch element, the characteristic frequency defining a boundary between a passband and a stopband.

3. The filter according to claim 2, wherein an ON resistance of the switch element of each of the at least two of the variable capacitance circuits and each of the at least one of the variable capacitance circuits is inversely proportional to a capacitance of the capacitor connected in series with the switch element.

4. The filter according to claim 2, further comprising the inductor connected to at least one selected from the input terminal, the output terminal, and the connection point.

5. The filter according to claim 4, wherein the switch element of one variable capacitance circuit is controlled to synchronize the switch element of the other variable capacitance circuit.

6. The filter according to claim 2, further comprising another switch element to provide an open or a short circuit between the input terminal and the output terminal, a characteristic of the high frequency filter upon the inductor being connected being changed to a characteristic of a band-pass filter or a low-pass filter by controlling the another switch element.

7. The filter according to claim 6, wherein an ON resistance of the switch element of each of the at least two of the variable capacitance circuits and each of the at least one of the variable capacitance circuits is inversely proportional to a capacitance of the capacitor connected in series with the switch element.

8. The filter according to claim 6, further comprising the inductor connected to at least one selected from the input terminal, the output terminal, and the connection point.

9. The filter according to claim 8, wherein the switch elements are controlled to switch synchronously.
